(19) United States
(12) Patent Application Publication
(10) Pub. No.: US 2024/0019780 A1
(43) Pub. Date: Jan. 18, 2024

(54) PHOTOSENSITIVE RESIN COMPOSITION, CURED FILM AND MICROLENS ARRAY

(71) Applicant: Advanced Echem Materials Company Limited, Taoyuan (TW)

(72) Inventors: Ya-Qian Chen, Taoyuan (TW); Yu-Chun Chen, Taoyuan (TW)

(73) Assignee: Advanced Echem Materials Company Limited, Taoyuan (TW)

(21) Appl. No.: 18/351,511

(22) Filed: Jul. 13, 2023

(30) Foreign Application Priority Data
Jul. 14, 2022 (TW) 111126397

(51) Int. Cl. G03F 7/031; G03F 7/004; G03F 7/029; G03F 7/00

(52) U.S. Cl. CPC G03F 7/031; G03F 7/0048; G03F 7/029; G03F 7/0005

(57) ABSTRACT

A photosensitive resin composition, a cured film and a microlens array are provided. The photosensitive resin composition includes resin (A), an ethylenically unsaturated monomer (B) and a photopolymerization initiator (C). The resin (A) includes an alkali-soluble resin (A-1). The alkali-soluble resin (A-1) includes a structural unit represented by following Formula (A1), a structural unit represented by following Formula (A2) or a combination thereof. The ethylenically unsaturated monomer (B) includes a compound represented by following Formula (B1).

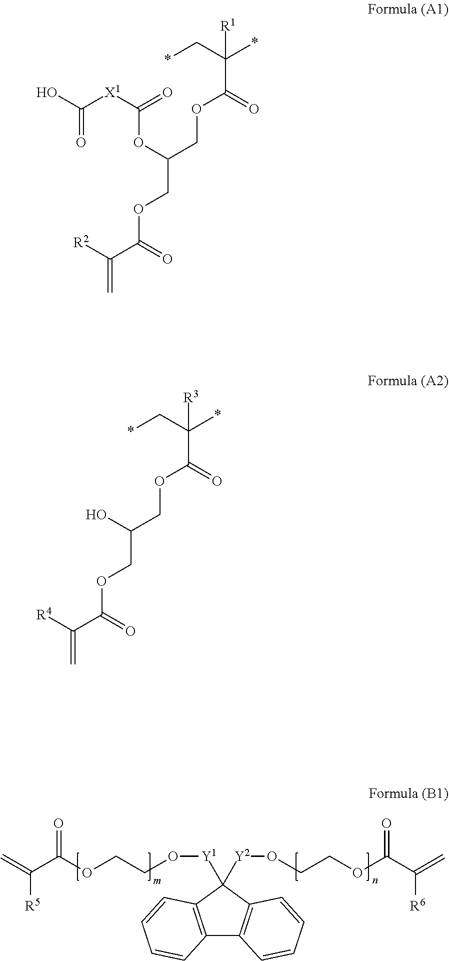

In Formula (A1), Formula (A2) and Formula (B1), the definition of R¹ to R⁶, X¹, Y¹, Y², m, n and * are the same as defined in the detailed description.

### CROSS-REFERENCE TO RELATED APPLICATION

This application claims the priority benefit of Taiwan application serial no. 111126397, filed on Jul. 14, 2022. The entirety of the above-mentioned patent application is hereby incorporated by reference herein and made a part of this specification.

### BACKGROUND

### Technical Field

The disclosure relates to a resin composition, particularly to a photosensitive resin composition, a cured film and a microlens array.

### Description of Related Art

With the vigorous development of technologies, the materials having good heat resistance, transmittance and refractive index are widely applied in display devices. At present, the refractive index of the cured film prepared by the material is often increased by adding inorganic particles. However, the cured film made of the inorganic particle-containing material has a phenomenon of poor transmittance.

### SUMMARY

The disclosure provides a photosensitive resin composition, a cured film, and a microlens array capable of providing good refractive index, transmittance, pattern feature and roundness.

A photosensitive resin composition of the disclosure includes a resin (A), an ethylenically unsaturated monomer (B) and a photopolymerization initiator (C). The resin (A) includes an alkali-soluble resin (A-1). The alkali-soluble resin (A-1) includes a structural unit represented by Formula (A1) as follows, a structural unit represented by Formula (A2) as follows, or a combination thereof. The ethylenically unsaturated monomer (B) includes a compound represented by Formula (B1) as follows.

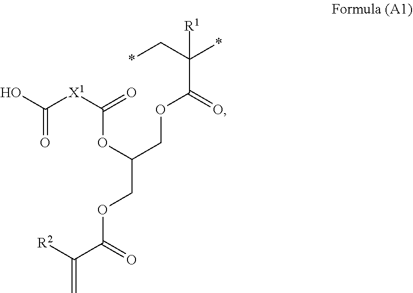

in Formula (A1), R¹ and R² each represent a hydrogen atom or methyl group,
X¹ represents ethylene group, propylene group, butylene group, 1,2-phenylene group, 1,2-cyclohexylene group, 1,2-cyclohexylene-1-ene group, 4,5-cyclohexylene-1-ene group or norbornenylene group, and * represents a bonding position;

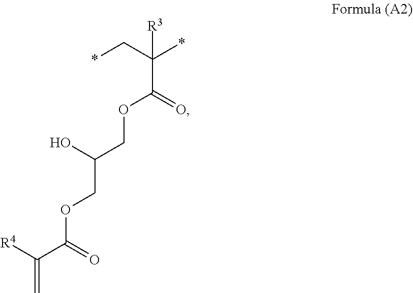

in Formula (A2), R³ and R⁴ each represent a hydrogen atom or a methyl group, and * represents a bonding position;

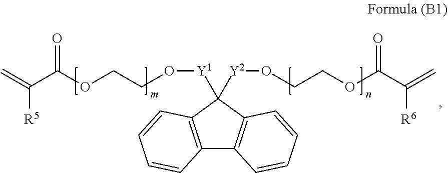

in Formula (B1), R⁵ and R⁶ each represent a hydrogen atom or a methyl group,
Y¹ and Y² each represent a methylene group, a substituted phenylene group, or a unsubstituted phenylene group,
m and n each represent an integer from 1 to 9.

In an embodiment of the disclosure, based on a usage amount of 100 parts by weight of the resin (A), a usage amount of the compound represented by Formula (B1) is 10 parts by weight to 40 parts by weight.

In an embodiment of the disclosure, in the alkali-soluble resin (A-1), based on a sum of 100 mol % of the structural unit represented by Formula (A1) and the structural unit represented by Formula (A2), the structural unit represented by Formula (A1) is 30 mol % to 60 mol %.

In an embodiment of the disclosure, a weight average molecular weight of the alkali-soluble resin (A-1) is 3,000 to 20,000.

In an embodiment of the disclosure, an acid value of the alkali-soluble resin (A-1) is 30 mgKOH/g to 100 mgKOH/g.

In an embodiment of the disclosure, the ethylenically unsaturated monomer (B) further includes 1,6-hexanediol diacrylate, tricyclodecane dimethanol diacrylate, diallyl terephthalate, ethylene glycol dimethacrylate, pentaerythritol triacrylate, ethoxylated pentaerythritol tetraacrylate, polydipentaerythritol hexaacrylate, trimethylolpropane tris(3-mercaptopropionate), 1,4-butanediol bis(3-mercaptobutyrate), tris[2-(3-mercaptopropoxy)ethyl]isocyanurate, 2,2-bis(((3-mercaptobutanoyl)oxy)methyl) propane-1,3-diyl bis(3-mercaptobutanoate), or a combination thereof.

In an embodiment of the disclosure, the photopolymerization initiator (C) includes a triazine-based compound, an acetophenone-based compound, a benzophenone-based compound, a diimidazole-based compound, a thioxanthone-based compound, a quinone-based compound, a phosphine oxide, an oxime ester-based compound, or combinations thereof.

In an embodiment of the disclosure, the photosensitive resin composition further includes a solvent (D). Based on a usage amount of 100 parts by weight of the resin (A), a usage amount of the solvent (D) is greater than 0 part by weight to less than or equal to 50 parts by weight.

In an embodiment of the disclosure, the photosensitive resin composition further includes a surfactant (E). The surfactant (E) includes a cationic-based surfactant, an anionic-based surfactant, a nonionic-based surfactant, an amphoteric-based surfactant, a polysiloxane-based surfactant, a fluorine-based surfactant, or a combination thereof.

In an embodiment of the disclosure, the photosensitive resin composition further includes an inorganic particle (F). The inorganic particle (F) includes zirconium oxide, titanium dioxide, or a combination thereof.

In an embodiment of the disclosure, the photosensitive resin composition further includes an inorganic particle (F). A refractive index of the inorganic particle (F) with respect to visible light is 1.67 or more.

In an embodiment of the disclosure, the photosensitive resin composition further includes an inorganic particle (F). An average particle diameter of the inorganic particle (F) is from 5 nm to 100 nm.

In an embodiment of the disclosure, the photosensitive resin composition further includes an inorganic particle (F). Based on a usage amount of 100 parts by weight of the resin (A), a usage amount of the inorganic particle (F) is greater than 0 part by weight to less than or equal to 400 parts by weight.

In an embodiment of the disclosure, based on a usage amount of 100 parts by weight of the resin (A), a usage amount of the ethylenically unsaturated monomer (B) is 5 parts by weight to 50 parts by weight, and a usage amount of the photopolymerization initiator (C) is 0.5 parts by weight to 5 parts by weight.

A cured film of the disclosure is formed by curing the photosensitive resin composition described above.

In an embodiment of the disclosure, a visible light transmittance of the cured film at a thickness of 3 μm is greater than 90%.

In an embodiment of the disclosure, a visible light refractive index of the cured film is 1.52 or more.

In an embodiment of the disclosure, the cured film is in the shape of a microlens and is located on an upper surface of a substrate, and a roundness thereof is 0.9≤L₂/L₁≤1.5 and 0.9≤L₃/L₁≤1.5. L₁ represents a maximum length of the cured film in a direction perpendicular to the substrate. The maximum length has an intersection with the upper surface of the substrate. In the first direction at an angle of 45° with the substrate, L₂ represents a length from the intersection to a surface of the cured film in the first direction. In the second direction at an angle of 0° with the substrate, L₃ represents a length from the intersection to the surface of the cured film in the second direction.

A microlens array of the disclosure is formed by the photosensitive resin composition described above.

Based on the above, the photosensitive resin composition of the disclosure includes an alkali-soluble resin (A-1) composed of a structural unit including a specific structure and an ethylenically unsaturated monomer (B) having a specific structure. Thus, when the photosensitive resin composition is used to form a cured film and a microlens array, the cured film and the microlens array may have good refractive index, transmittance, pattern feature and roundness, thereby suitable for optical elements or display devices.

To make the features and advantages of the disclosure to be comprehended more easily, embodiments and drawings are described in detail as follows.

### BRIEF DESCRIPTION OF THE DRAWINGS

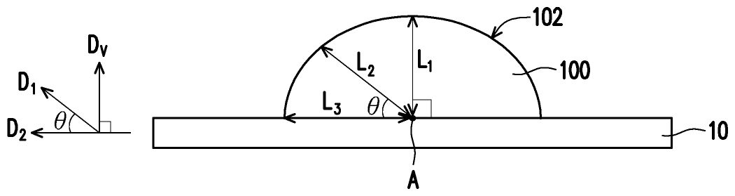

The FIG. 1s a schematic diagram of the present disclosure for evaluating the roundness.

### DESCRIPTION OF THE EMBODIMENTS

### <Photosensitive Resin Composition>

The disclosure provides a photosensitive resin composition including a resin (A), an ethylenically unsaturated monomer (B) and a photopolymerization initiator (C). In addition, the photosensitive resin composition of the disclosure may further include at least one of a solvent (D), a surfactant (E) and an inorganic particle (F) as needed. The components are described hereinafter in detail.

### Resin (A)

The resin (A) includes an alkali-soluble resin (A-1). The alkali-soluble resin (A-1) includes a structural unit represented by Formula (A1) as follows, a structural unit represented by Formula (A2) as follows, or a combination thereof. The alkali-soluble resin (A-1) may include one structural unit or a combination of two or more structural units. In this embodiment, a weight average molecular weight of the alkali-soluble resin (A-1) is 3,000 to 20,000, preferably 4,000 to 12,000. An acid value of the alkali-soluble resin (A-1) is 30 mgKOH/g to 100 mgKOH/g, preferably 35 mgKOH/g to 80 mgKOH/g.

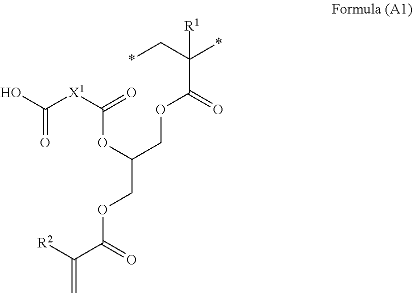

In Formula (A1), R¹ and R² each represent a hydrogen atom or methyl group, preferably R¹ represents methyl group and R² represent a hydrogen atom;
X¹ represents ethylene group, propylene group, butylene group, 1,2-phenylene group, 1,2-cyclohexylene group, 1,2-cyclohexylene-1-ene group, 4,5-cyclohexylene-1-ene group or norbornenylene group, preferably 4,5-cyclohexylene-1-ene group; and * represents a bonding position.

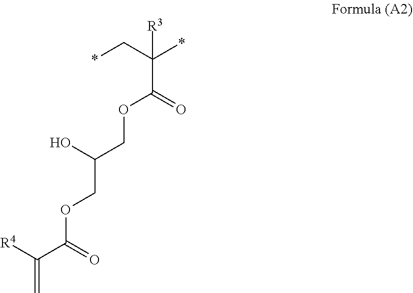

In Formula (A2), R³ and R⁴ each represent a hydrogen atom or a methyl group, preferably R³ represents methyl group and R⁴ represent a hydrogen atom; and * represents a bonding position.

For example, the alkali-soluble resin (A-1) may be one alkali-soluble resin or a combination of two or more alkali-soluble resins. The alkali-soluble resin (A-1) may further include a structural unit composed of an acrylic-based compound, a styrene-based compound, a maleimide-based compound or other suitable monomers.

In the alkali-soluble resin (A-1), based on a sum of 100 mol % of the structural unit represented by Formula (A1) and the structural unit represented by Formula (A2), the structural unit represented by Formula (A1) is 30 mol % to 60 mol %, preferably 35 mol % to 50 mol %.

When the alkali-soluble resin (A-1) in the photosensitive resin composition includes a structural unit represented by Formula (A1), a structural unit represented by Formula (A2), or a combination thereof, the cured film formed by the photosensitive resin composition is able to provide better pattern feature and roundness, and to provide good refractive index and transmittance at the same time.

### Ethylenically Unsaturated Monomer (B)

The ethylenically unsaturated monomer (B) includes a compound represented by Formula (B1) as follows.

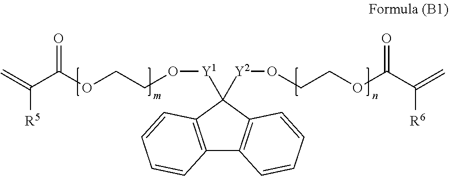

In Formula (B1), R⁵ and R⁶ each represent a hydrogen atom or a methyl group, preferably a hydrogen atom;
Y¹ and Y² each represent a methylene group, a substituted phenylene group, or a unsubstituted phenylene group, preferably a unsubstituted phenylene group;
m and n each represent an integer from 1 to 9, preferably a sum of m and n is an integer from 2 to 10.

The ethylenically unsaturated monomer (B) may be used alone or in combination. For example, the ethylenically unsaturated monomer (B) may further include a monomer including difunctional groups or a monomer including polyfunctional groups. The monomer including polyfunctional groups represents the functional groups included in the monomer more than 2. The functional group includes a hydroxyl group, an ester group, a carboxyl group, a thiol group, or a combination thereof. In this embodiment, the ethylenically unsaturated monomer (B) may further include 1,6-hexanediol diacrylate, tricyclodecane dimethanol diacrylate, diallyl terephthalate, ethylene glycol dimethacrylate, pentaerythritol triacrylate, ethoxylated pentaerythritol tetraacrylate, polydipentaerythritol hexaacrylate, trimethylolpropane tris(3-mercaptopropionate), 1,4-butanediol bis(3-mercaptobutyrate), tris[2-(3-mercaptopropoxy)ethyl]isocyanurate, 2,2-bis(((3-mercaptobutanoyl)oxy)methyl) propane-1,3-diyl bis(3-mercaptobutanoate), or a combination thereof, preferably tricyclodecane dimethanol diacrylate.

Based on a usage amount of 100 parts by weight of the resin (A), a usage amount of the ethylenically unsaturated monomer (B) is 5 parts by weight to 50 parts by weight, preferably 22 parts by weight to 27 parts by weight.

Based on a usage amount of 100 parts by weight of the resin (A), a usage amount of the compound represented by Formula (B1) is 10 parts by weight to 40 parts by weight, preferably 11 parts by weight to 27 parts by weight. When the usage amount of the compound represented by Formula (B1) is within the aforementioned range, the cured product formed by the photosensitive resin composition is able to provide good refractive index, transmittance, pattern feature and roundness.

When the ethylenically unsaturated monomer (B) in the photosensitive resin composition includes the compound represented by Formula (B1), the cured product formed by the photosensitive resin composition is able to provide better roundness, and to provide good refractive index, transmittance and pattern feature at the same time.

### Photopolymerization Initiator (C)

The photopolymerization initiator (C) is not particularly limited, and any suitable photopolymerization initiator may be selected according to needs. For example, the photopolymerization initiator (C) includes a triazine-based compound, an acetophenone-based compound, a benzophenone-based compound, a diimidazole-based compound, a thioxanthone-based compound, a quinone-based compound, a phosphine oxide, an oxime ester-based compound or other suitable photopolymerization initiators. The photopolymerization initiator (C) may be used alone or in combination. In this embodiment, the photopolymerization initiator (C) is preferably an acetophenone-based compound.

Based on a usage amount of 100 parts by weight of the resin (A), a usage amount of the photopolymerization initiator (C) is 0.5 parts by weight to 5 parts by weight, preferably 1 part by weight to 3 parts by weight, more preferably 1.5 parts by weight to 2.5 parts by weight.

### Solvent (D)

The solvent (D) is not particularly limited, and any suitable solvent may be selected according to needs. For example, the solvent (D) may include propylene glycol methyl ether acetate (PGMEA), ethyl 3-ethoxypropionate (EEP), ethyl 2-hydroxypropanoate, butyl lactate, phenylmethanol, 3-methoxybutyl acetate (MBA), 3-methoxy-3-methyl-1-butanol, gamma-butyrolactone, propylene glycol mono-n-butyl ether or other suitable solvents. The solvent (D) may be used alone or in combination. In this embodiment, the solvent (D) is preferably propylene glycol methyl ether acetate.

Based on a usage amount of 100 parts by weight of the resin (A), a usage amount of the solvent (D) may be 0 part by weight to 50 parts by weight (that is, 0 parts by weight, or greater than 0 part by weight to less than or equal to 50 parts by weight), preferably 0 part by weight or 14 parts by weight to 39 parts by weight. When the photosensitive resin composition does not include the solvent (D), the solvent in the photosensitive resin composition may be from the resin (A). Regardless of whether the photosensitive resin composition includes the solvent (D) or not, the cured film formed by the photosensitive resin composition is able to provide good refractive index, transmittance, pattern characteristics and roundness.

### Surfactant (E)

The surfactant (E) is not particularly limited, and any suitable surfactant may be selected according to needs. For example, the surfactant (E) may include a cationic-based surfactant, an anionic-based surfactant, a nonionic-based surfactant, an amphoteric-based surfactant, a polysiloxane-based surfactant, a fluorine-based surfactant or other suitable surfactants. The surfactant (E) may be used alone or in combination. In this embodiment, the surfactant (E) is preferably a polysiloxane-based surfactant.

Based on a usage amount of 100 parts by weight of the resin (A), a usage amount of the surfactant (E) is 5 parts by weight to 50 parts by weight, preferably 10 parts by weight to 35 parts by weight.

### Inorganic Particle (F)

The inorganic particle (F) is not particularly limited, and any suitable inorganic particle may be selected according to needs. For example, a refractive index of the inorganic particle (F) with respect to visible light is 1.67 or more, preferably 1.78 or more. An average particle diameter of the inorganic particle (F) is from 5 nm to 100 nm, preferably from 26 nm to 49 nm.

The inorganic particle (F) may be used alone or in combination. In this embodiment, the inorganic particle (F) includes zirconium oxide, titanium dioxide, or a combination thereof, preferably titanium dioxide or a combination of titanium dioxide and zirconium oxide.

Based on a usage amount of 100 parts by weight of the resin (A), a usage amount of the inorganic particle (F) may be 0 part by weight to 400 parts by weight, preferably greater than 0 part by weight to less than or equal to 400 parts by weight, more preferably 93 parts by weight to 398 parts by weight. Regardless of whether the photosensitive resin composition includes the inorganic particle (F) or not, the cured film formed by the photosensitive resin composition is able to provide good refractive index, transmittance, pattern characteristics and roundness. When the photosensitive resin composition includes the inorganic particle (F), the cured film formed by the photosensitive resin composition is able to provide better refractive index.

### <Preparation of Photosensitive Resin Composition>

The preparation of the photosensitive resin composition is not particularly limited. For example, the resin (A), the ethylenically unsaturated monomer (B) and the photopolymerization initiator (C) are stirred in a mixer to be mixed uniformly into a solution state, and a solvent (D), a surfactant (E), an inorganic particle (F) or other suitable additives may also be added if necessary. After mixing them uniformly, a liquid photosensitive resin composition is obtained.

### <Manufacturing Process of Cured Film>

An exemplary embodiment of the disclosure provides a cured film formed by curing the photosensitive resin composition above.

The cured film may be formed by coating the photosensitive resin composition above on a substrate to form a coating film and performing pre-bake, exposure, development, and post-bake on the coating film. For example, after the photosensitive resin composition is coated on the substrate to form a coating film, pre-bake is performed at a temperature of 110° C. for 120 seconds. Next, the pre-baked coating film is exposed with a light at 150 mJ/cm². Then, the exposed coating film is developed for 80 seconds. Next, the developed coating film was washed with distilled water and nitrogen gas was blown to dry the coating film. Then, post-bake is performed at 230° C. for 40 minutes to form a cured film with a thickness of 3 μm to 4 μm on the substrate.

The substrate may be a glass substrate, a plastic base material (for example, a polyether sulfone (PES) board, a polycarbonate (PC) board, or a polyimide (PI) film), or other light-transmitting substrates, and the type thereof is not particularly limited.

The coating method is not particularly limited, but a spray coating method, a roll coating method, a spin coating method, or the like may be used, and in general, a spin coating method is widely used. In addition, a coating film is formed, and then, in some cases, residual solvent may be partially removed under reduced pressure.

The developing solution is not particularly limited, and a suitable developing solution may be selected as needed. For example, the developing solution may be sodium hydrogen carbonate (NaHCO₃) solution, and the concentration thereof may be 0.1 wt %.

In this embodiment, a visible light transmittance of the cured film at a thickness of 3 μm is greater than 90%. A visible light refractive index of the cured film is 1.52 or more, preferably 1.72 or more.

In this embodiment, the cured film is in the shape of a microlens and is located on an upper surface of a substrate. A roundness of the cured film is 0.9≤L₂/L₁≤1.5 and 0.9≤L₃/L₁≤1.5. Please refer to the FIGURE, L₁ represents a maximum length of the cured film 100 in a direction D_{V} perpendicular to the substrate 10. L₁ is the thickness (film thickness) of the cured film 100. The maximum length L₁ has an intersection A with the substrate. In the first direction D₁ at an angle (0) of 45° with the substrate 10, L₂ represents a length from the intersection A to a surface 102 of the cured film in the first direction D₁. In the second direction D₂ at an angle of 0° with the substrate 10, L₃ represents a length from the intersection A to the surface 102 of the cured film in the second direction D₂. The second direction D₂ is perpendicular to the direction D_{V}, and forms an angle (0) of 45° with the first direction D₁.

### <Manufacturing Process of Microlens Array>

An exemplary embodiment of the disclosure provides a microlens array formed by the photosensitive resin composition above. In this embodiment, the micolens array is the cured film above.

The manufacturing process of the microlens array may be the same as the above manufacturing process of cured film, and is not repeated herein.

The disclosure is described hereinafter in detail with reference to some examples. The following examples are provided to describe the disclosure, and the scope of the disclosure includes the categories described in the following claims, their equivalents, and their modifications. The disclosure is not limited to the scope of those examples.

### Examples of Photosensitive Resin Composition and Cured Film

Example 1 to Example 5 and Comparative example 1 to Comparative example 3 of the photosensitive resin composition and the cured film are described below:

### Example 1

a. Photosensitive Resin Composition

100 parts by weight of the resin (A-1), 23.2 parts by weight of the ethylenically unsaturated monomer (B-1), 1.6 parts by weight of the photopolymerization initiator (C-1), 16.4 parts by weight of the surfactant (E-1), 47.0 parts by weight of the inorganic particle (F-1) and 46.2 parts by weight of the inorganic particle (F-2) were added in 38.8 parts by weight of the solvent (D-1). After stirring uniformly with a stirrer, the photosensitive resin composition of Example 1 was obtained.

b. Cured film

Each photosensitive resin composition prepared in the examples was coated on a glass substrate by a spin coating method (spin coater model: MS-A150, manufactured by MIKASA Corporation, rotation speed: about 195 rpm). Next, pre-bake was performed at a temperature of 110° C. for 120 seconds to form a film. Then, a photomask with a circular penetration pattern with 1 μm to 100 μm line width/spacing was placed over the pre-baked coating film with a 70 μm separation between the film surface and the photomask, and then the pre-baked coating film is exposed at 150 mJ/cm² using a high-pressure mercury lamp (including g, h, i lines) (model: ELS106SA, manufactured by ELS System Technology Co., Ltd.) to form a semi-finished product. Next, development was performed at a temperature of 24° C. using NaHCO₃ solution having a concentration of 0.1 wt % as a developing solution for 80 seconds. Then, the developed coating film was washed with distilled water and nitrogen gas was blown to dry the coating film. Next, post-bake was performed at 230° C. for 40 minutes to obtain the cured films with a specific pattern thickness. The refractive index, transmittance, pattern feature and roundness of the obtained cured films were evaluated by each of the following evaluation methods, and the results thereof are as shown in Table 2.

### Example 2 to Example 5 and Comparative Example 1 to Comparative Example 3

The photosensitive resin compositions of Example 2 to Example 5 and Comparative example 1 to Comparative example 3 were prepared using the same steps as Example 1, and the difference thereof is: the type and the usage amount of the components of the photosensitive resin compositions were changed (as shown in Table 2), wherein the components/compounds corresponding to the symbols in Table 2 are shown in Table 1. The obtained photosensitive resin compositions were made into cured films and evaluated by each of the following evaluation methods, and the results thereof are as shown in Table 2.

TABLE 1

| | Symbol | Components/compounds |
|---|---|---|
| Resin (A) | A-1 | Resin including the structural unit represented by Formula |
| | | (A1) and the structural unit represented by Formula (A2), |
| | | wherein R¹ represents methyl group, R² represents a |
| | | hydrogen atom, X¹ represents 4,5-cyclohexylene-1-ene |
| | | group, R³ represents methyl group, and R⁴ represents a |
| | | hydrogen atom. |
| | | Resin (A-1) is an alkali-soluble resin, a weight average |
| | | molecular weight thereof is 4,000 to 12,000, and an acid |
| | | value thereof is 35 mgKOH/g to 80 mgKOH/g |
| | | (manufactured by SHOWA DENKO K.K.). |
| | | In the resin (A-1), based on a sum of 100 mol % of the |
| | | structural unit represented by Formula (A1) and the |
| | | structural unit represented by Formula (A2), the structural |
| | | unit represented by Formula (A1) is 35 mol % to 50 mol %. |
| | A-2 | Resin including a structural unit represented by Formula |
| | | (A3) and a structural unit represented by Formula (A4), |
| | | 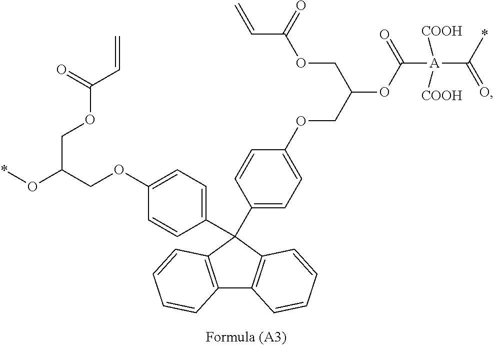 |
| | | 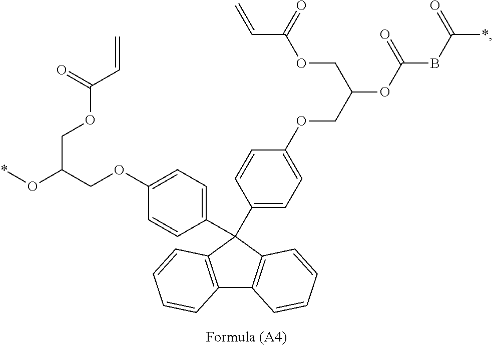 |
| | | wherein A represents |
| | | 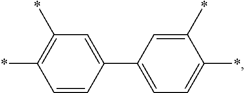 |
| | | B represents |
| | | 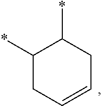 [SMILES: *C1CC=CCC1*] |
| | | and * represents a bonding position. |
| | | Resin (A-2) is an alkali-soluble resin, a weight average |
| | | molecular weight thereof is 4,000 to 6,000, and an acid |
| | | value thereof is 90 mgKOH/g to 120 mgKOH/g |
| | | (manufactured by Miwon Commercial Co., Ltd). |
| Ethylenically | B-1 | Compound represented by Formula (B1), wherein R⁵ |
| unsaturated | | represents a hydrogen atom, R⁶ represents a hydrogen |
| monomer (B) | | atom, Y¹ represents an unsubstituted phenylene group, Y² |
| | | represents an unsubstituted phenylene group, m represents |
| | | 1, and n represents 1. |
| | | Ethylenically unsaturated monomer (B-1) is a modified |
| | | bisphenol fluorene diacrylate. |
| | B-2 | Polydipentaerythritol hexaacrylate |
| | B-3 | Tricyclodecane dimethanol diacrylate |
| Photopolymerization | C-1 | 2-Benzyl-2-(dimethylamino)-4-morpholinobutyrophenone |
| initiator (C) | | |
| Solvent (D) | D-1 | Propylene glycol methyl ether acetate |
| Surfactant (E) | E-1 | Polyether modified polydimethylsiloxane (trade name: |
| | | BYK-307, manufactured by BYK Chemie GmbH). |
| Inorganic particle | F-1 | Titanium dioxide, and an average particle diameter thereof |
| (F) | | is 26.4 nm. |
| | F-2 | Zirconium oxide, and an average particle diameter thereof |
| | | is 48.6 nm. |

TABLE 2

| Component | | Examples | | | | | Comparative examples | | |
|---|---|---|---|---|---|---|---|---|---|
| (unit: parts by weight) | | 1 | 2 | 3 | 4 | 5 | 1 | 2 | 3 |
| Resin (A) | A-1 | 100 | 100 | 100 | 100 | 100 | 100 | 100 | — |
| | A-2 | — | — | — | — | — | — | — | 100 |
| Ethylenically | B-1 | 23.2 | 22.9 | 11.4 | 23.2 | 26.5 | — | — | 34.4 |
| unsaturated | B-2 | — | — | — | — | — | 22.9 | — | — |
| monomer (B) | B-3 | — | — | — | — | — | — | 22.9 | — |
| Photopoly- | C-1 | 1.6 | 2.3 | 2.3 | 1.8 | 2.1 | 2.3 | 2.3 | 2.8 |
| merization | | | | | | | | | |
| initiator (C) | | | | | | | | | |
| Solvent (D) | D-1 | 38.8 | 14.9 | 14.9 | — | 37.5 | 14.9 | 14.9 | 105.3 |
| Surfactant (E) | E-1 | 16.4 | 34.3 | 34.3 | 15.7 | 10.6 | 34.3 | 34.3 | 24.3 |
| Inorganic | F-1 | 47.0 | 200.6 | 200.6 | 120.4 | — | 200.6 | 200.6 | 69.6 |
| particle (F) | F-2 | 46.2 | 196.6 | 196.6 | — | — | 196.6 | 196.6 | 68.4 |
| Evaluation | Refractive index | 1.60 | 1.72 | 1.70 | 1.62 | 1.52 | 1.67 | 1.68 | 1.67 |
| results | Transmittance (%) | 94.9 | 90.9 | 91.3 | 92.5 | >99 | 91.5 | 91.1 | 93.7 |
| | Pattern feature | ∘ | ∘ | ∘ | ∘ | ∘ | ∘ | x | x |
| | Roundness | ∘ | ∘ | ∘ | ∘ | ∘ | x | x | x |

### <Evaluation Methods>

a. Refractive Index

Each photosensitive resin composition prepared in the examples was coated on a chromium substrate by a spin coating method (spin coater model: MS-A150, manufactured by MIKASA Corporation, rotation speed: about 600 rpm). Next, pre-bake was performed at a temperature of 110° C. for 120 seconds to form a film. Then, the pre-baked coating film is exposed at 150 mJ/cm² using a high-pressure mercury lamp (including g, h, i lines) (model: ELS106SA, manufactured by ELS System Technology Co., Ltd.). Next, post-bake was performed at 230° C. for 40 minutes to obtain the cured films at a thickness of 1 μm.

The prepared cured film (thickness: 1 μm) was measured for a refractive index in the visible light region (for example, the wavelength of 550 nm) via an Ellipsometer (Model: M-2000VI, manufactured by Titan Electro-Optics Co., Ltd.). When the refractive index is greater, the cured film has good spotlight effect.

b. Transmittance

The prepared cured film (thickness: 3 μm) was measured for average transmittance at wavelengths of 380 nm to 780 nm via a Multi-channel spectrometer (Model: MCPD-3000, manufactured by OTSUKA TECH ELECTRONICS CO., LTD.).

c. Pattern Feature

The prepared cured film (thickness: 3 μm) was observed via a Color 3D Laser Microscope (Model: VK-9700, manufactured by Keyence Corporation) at a magnification of 1,500× to observe whether the 6 μm pattern exists on the substrate and whether there is photosensitive resin composition remaining on the substrate at the edge of the pattern to evaluate the pattern feature. When the pattern still exists on the substrate and no photosensitive resin composition remains at the edge of the pattern, the cured film has good pattern feature.

The evaluation criteria of pattern feature are as follows:
◯: 6 μm pattern still exists on the substrate and no photosensitive resin composition remains at the edge of the pattern on the substrate;
x: 6 μm pattern does not exist on the substrate, or photosensitive resin composition remains at the edge of the pattern on the substrate.
   d. Roundness

The prepared cured film (thickness: 3 μm) was observed via a field emission scanning electron microscope (FESEM) (Model: SU8000, manufactured by Hitachi Co., Ltd) at a magnification of 10,000× to obtain a maximum length (L₁), a length measured at an angle of to the substrate (L₂) and a length measured at an angle of 0° to the substrate (L₃)(as shown in the FIGURE) to evaluate the roundness. When a ratio of L₂ to L₁ is in the range from 0.9 to 1.5 and a ratio of L₃ to L₁ is in the range from 0.9 to 1.5, the cured film has good microlens shape. The evaluation criteria of roundness are as follows:

◯:0.9≤L₂/L₁≤1.5 and 0.9≤L₃/L₁≤1.5;

x: L₂/L₁<0.9,1.5<L₂/L₁,L₃/L₁<0.9 or 1.5<L₃/L₁.

### <Evaluation Results>

It may be seen from Table 2 that the cured films formed by the photosensitive resin composition including the alkali-soluble resin (A-1) composed of at least one of the structural units having a specific structure and the ethylenically unsaturated monomer (B) having a specific structure of Examples 1 to 5 have good refractive index, transmittance, pattern feature and roundness, and may be used as microlens array and may be suitable for optical elements or display devices. In contrast, the cured films formed by the photosensitive resin composition in which the photosensitive resin composition does not include the alkali-soluble resin (A-1) composed of at least one of the structural units having a specific structure or the ethylenically unsaturated monomer (B) having a specific structure of Comparative examples 1 to 3 have poor pattern feature and/or roundness.

In addition, compared to the cured films (Comparative examples 1 to 2) formed by the photosensitive resin composition in which the ethylenically unsaturated monomer (B) does not include the compound having specific structure, the cured films (Examples 1 to 5) prepared by the photosensitive resin composition in which the ethylenically unsaturated monomer (B) includes the compound having specific structure have better roundness, and have good refractive index, transmittance and pattern feature at the same time.

In addition, compared to the cured film (Comparative example 3) formed by the photosensitive resin composition in which the alkali-soluble resin (A-1) does not include at least one of the structural units having a specific structure, the cured films (Examples 1 to 5) prepared by the photosensitive resin composition in which the alkali-soluble resin (A-1) includes at least one of the structural units having a specific structure have better pattern feature and roundness, and have good refractive index and transmittance at the same time.

In addition, based on the usage amount of 100 parts by weight of the resin (A), the cured films (Examples 1 to 5) prepared by the photosensitive resin composition in which the usage amount of the ethylenically unsaturated monomer (B) including the compound having the specific structure, namely the compound represented by Formula (B1), is 10 parts by weight to 40 parts by weight have good refractive index, transmittance, pattern feature and roundness.

In addition, the cured films prepared by the photosensitive resin composition including the solvent (D) (Examples 1 to 3 and 5) and not including the solvent (D) (Example 4) all have good refractive index, transmittance, pattern feature and roundness.

In addition, the cured films prepared by the photosensitive resin composition including the inorganic particle (F) (Examples 1 to 4) and not including the inorganic particle (F) (Example 5) all have good refractive index, transmittance, pattern feature and roundness. Compared to the cured film (Example 5) formed by the photosensitive resin composition not including the inorganic particle (F), the cured films (Examples 1 to 4) prepared by the photosensitive resin composition including the inorganic particle (F) have better refractive index, and have good transmittance, pattern feature and roundness at the same time.

Based on the above, when the photosensitive resin composition of the disclosure includes the alkali-soluble resin (A-1) composed of at least one of the structural units having a specific structure and an ethylenically unsaturated monomer (B) having a specific structure, the cured film formed by the photosensitive resin composition has good refractive index, transmittance, pattern feature and roundness. Therefore, the photosensitive resin composition may be used for microlens array, and suitable for optical elements or display devices, thereby improving the performance of a device or an element formed thereby.

Although the disclosure has been disclosed in the embodiments above, they are not intended to limit the disclosure. Anyone with ordinary knowledge in the relevant technical field can make changes and modifications without departing from the spirit and scope of the disclosure. The scope of protection of the disclosure shall be subject to those defined by the claims attached.

What is claimed is:

1. A photosensitive resin composition, comprising:
a resin (A) comprising an alkali-soluble resin (A-1), the alkali-soluble resin (A-1) comprising a structural unit represented by Formula (A1) as follows, a structural unit represented by Formula (A2) as follows, or a combination thereof;
an ethylenically unsaturated monomer (B) comprising a compound represented by Formula (B1) as follows; and
a photopolymerization initiator (C): 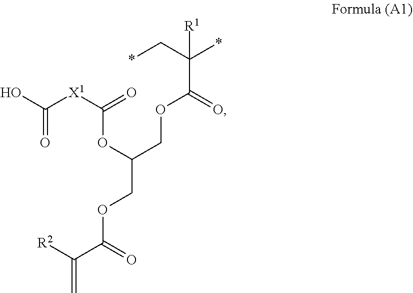
in Formula (A1), R¹ and R² each represent a hydrogen atom or methyl group,
X¹ represents ethylene group, propylene group, butylene group, 1,2-phenylene group, 1,2-cyclohexylene group, 1,2-cyclohexylene-1-ene group, 4,5-cyclohexylene-1-ene group or norbornenylene group, and * represents a bonding position; 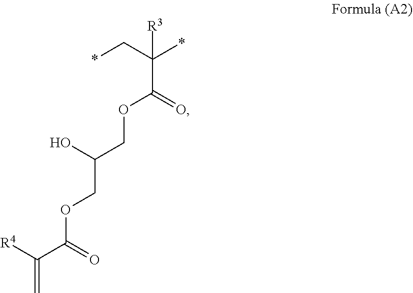
in Formula (A2), R³ and R⁴ each represent a hydrogen atom or a methyl group, and * represents a bonding position; 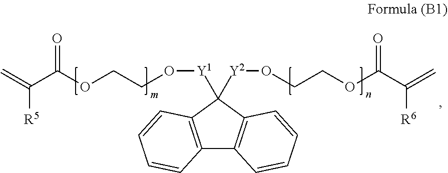
in Formula (B1), R⁵ and R⁶ each represent a hydrogen atom or a methyl group,
Y¹ and Y² each represent a methylene group, a substituted phenylene group, or a unsubstituted phenylene group,
m and n each represent an integer from 1 to 9.

2. The photosensitive resin composition according to claim 1, wherein based on a usage amount of 100 parts by weight of the resin (A), a usage amount of the compound represented by Formula (B1) is 10 parts by weight to 40 parts by weight.

3. The photosensitive resin composition according to claim 1, wherein in the alkali-soluble resin (A-1), based on a sum of 100 mol % of the structural unit represented by Formula (A1) and the structural unit represented by Formula (A2), the structural unit represented by Formula (A1) is 30 mol % to 60 mol %.

4. The photosensitive resin composition according to claim 1, wherein a weight average molecular weight of the alkali-soluble resin (A-1) is 3,000 to 20,000.

5. The photosensitive resin composition according to claim 1, wherein an acid value of the alkali-soluble resin (A-1) is 30 mgKOH/g to 100 mgKOH/g.

6. The photosensitive resin composition according to claim 1, wherein the ethylenically unsaturated monomer (B) further comprises 1,6-hexanediol diacrylate, tricyclodecane dimethanol diacrylate, diallyl terephthalate, ethylene glycol dimethacrylate, pentaerythritol triacrylate, ethoxylated pentaerythritol tetraacrylate, polydipentaerythritol hexaacrylate, trimethylolpropane tris(3-mercaptopropionate), 1,4-butanediol bis(3-mercaptobutyrate), tris[2-(3-mercaptopropoxy)ethyl]isocyanurate, 2,2-bis(((3-mercaptobutanoyl)oxy)methyl) propane-1,3-diyl bis(3-mercaptobutanoate), or a combination thereof.

7. The photosensitive resin composition according to claim 1, wherein the photopolymerization initiator (C) comprises a triazine-based compound, an acetophenone-based compound, a benzophenone-based compound, a diimidazole-based compound, a thioxanthone-based compound, a quinone-based compound, a phosphine oxide, an oxime ester-based compound, or combinations thereof.

8. The photosensitive resin composition according to claim 1, further comprising a solvent (D), wherein based on a usage amount of 100 parts by weight of the resin (A), a usage amount of the solvent (D) is greater than 0 part by weight to less than or equal to 50 parts by weight.

9. The photosensitive resin composition according to claim 1, further comprising a surfactant (E), wherein the surfactant (E) comprises a cationic-based surfactant, an anionic-based surfactant, a nonionic-based surfactant, an amphoteric-based surfactant, a polysiloxane-based surfactant, a fluorine-based surfactant, or a combination thereof.

10. The photosensitive resin composition according to claim 1, further comprising an inorganic particle (F), wherein the inorganic particle (F) comprises zirconium oxide, titanium dioxide, or a combination thereof.

11. The photosensitive resin composition according to claim 1, further comprising an inorganic particle (F), wherein a refractive index of the inorganic particle (F) with respect to visible light is 1.67 or more.

12. The photosensitive resin composition according to claim 1, further comprising an inorganic particle (F), wherein an average particle diameter of the inorganic particle (F) is from nm to 100 nm.

13. The photosensitive resin composition according to claim 1, further comprising an inorganic particle (F), wherein based on a usage amount of 100 parts by weight of the resin (A), a usage amount of the inorganic particle (F) is greater than 0 part by weight to less than or equal to 400 parts by weight.

14. The photosensitive resin composition according to claim 1, wherein based on a usage amount of 100 parts by weight of the resin (A), a usage amount of the ethylenically unsaturated monomer (B) is 5 parts by weight to 50 parts by weight, and a usage amount of the photopolymerization initiator (C) is 0.5 parts by weight to 5 parts by weight.

15. A cured film formed by curing the photosensitive resin composition according to claim 1.

16. The cured film according to claim 15, a visible light transmittance thereof at a thickness of 3 μm is greater than 90%.

17. The cured film according to claim 15, a visible light refractive index thereof is 1.52 or more.

18. The cured film according to claim 15, which is in the shape of a microlens and is located on an upper surface of a substrate, and a roundness thereof is 0.9≤L₂/L₁≤1.5 and 0.9≤L₃/L₁≤1.5, wherein L₁ represents a maximum length of the cured film in a direction perpendicular to the substrate, the maximum length has an intersection with the upper surface of the substrate,
in the first direction at an angle of 45° with the substrate, L₂ represents a length from the intersection to a surface of the cured film in the first direction,
in the second direction at an angle of 0° with the substrate, L₃ represents a length from the intersection to the surface of the cured film in the second direction.

19. A microlens array formed by the photosensitive resin composition according to claim 1.
